(19) United States
(12) Patent Application Publication
(10) Pub. No.: US 2003/0084389 A1
(43) Pub. Date: May 1, 2003

(54) Method and apparatus for flexible memory for defect tolerance

(76) Inventors: Sailesh Kottapalli, Milpitas, CA (US); Mahadev Nemani, Sunnyvale, CA (US); Kenneth R. Smits, San Ramon, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/033,155

(22) Filed: Oct. 25, 2001

(51) Int. Cl. G01R 31/28

(52) U.S. Cl. 714/733

(57) ABSTRACT

A cache memory that is flexible to allow for defect tolerance by utilizing a status bit for each cache line to indicate whether the cache line is functional or contains a defect.

### 2. BACKGROUND INFORMATION

As the technology for manufacturing integrated circuits advances and demand for increased cache memory performance, larger cache memories with smaller memory cells are desired. Typically, computing systems integrate cache memory with the micro-controller or microprocessor to increase performance by storing frequently accessed main memory locations in the cache memory.

Modem integrated circuit (IC) devices include large numbers of gates on a single semiconductor chip, with these gates interconnected so as to perform multiple and complex functions. The fabrication of an IC incorporating such Very Large Scale Integration (VLSI) must be error free, as a manufacturing defect may prevent the IC from performing all of the functions that an IC is designed to perform. Such demands require verification of the design of the IC and also various types of electrical testing after the IC is manufactured.

However, as the complexity of the ICs increase, so does the cost and complexity of verifying and electrically testing the individual IC. Testing and manufacturing costs and design complexity increase dramatically because of new manufacturing processes and smaller memory cells more susceptible to manufacturing defects.

To improve manufacturing yields, one typical solution is implementing redundant memory arrays, which is termed “redundancy”. For example, a redundant array is enabled to replace a defective array within the memory. However, redundant arrays increase the size and manufacturing cost of the memory array. Another typical solution is in U.S. Pat. No. 6,192,486, which bypasses defective memory arrays with a register and steering means. However, this solution increases design complexity by requiring address index and register comparison means and decreases the array size by a predetermined amount.

### BRIEF DESCRIPTION OF THE DRAWINGS

Subject matter is particularly pointed out and distinctly claimed in the concluding portion of the specification. The claimed subject matter, however, both as to organization and method of operation, together with objects, features, and advantages thereof, may best be understood by reference to the following detailed description when read with the accompanying drawings in which:

FIG. 1 is a block diagram of a cache memory in accordance with one embodiment.

FIG. 2 is a schematic diagram in accordance with one embodiment.

### DETAILED DESCRIPTION

In the following detailed description, numerous specific details are set forth in order to provide a thorough understanding of the claimed subject matter. However, it will be understood by those skilled in the art that the claimed subject matter may be practiced without these specific details. In other instances, well-known methods, procedures, components and circuits have not been described in detail so as not to obscure the claimed subject matter.

In general, designers and test engineers desire to increase manufacturing yields of integrated devices. Typically, redundancy arrays are implemented to replace defective memory arrays. However, redundant arrays increase the size of the memory and results in increased manufacturing costs. Thus, it is desirable to increase manufacturing yields of memory with minimal or no redundant arrays and with minimal logic.

Cache memories have a range of different architectures with respect to addresses locations mapped to predetermined cache locations. For example, cache memories may be direct mapped or fully associative. Alternatively, another cache memory is a set associative cache, which is a compromise between a direct mapped cache and fully associative cache. In a direct mapped cache, there is one address location in each set. Conversely, a fully associative cache that is N-way associative has a total number of N blocks in the cache. Finally, a set associative cache, commonly referred to as N-way set associative, divides the cache into a plurality of N ways wherein each address is searched associatively for a tag.

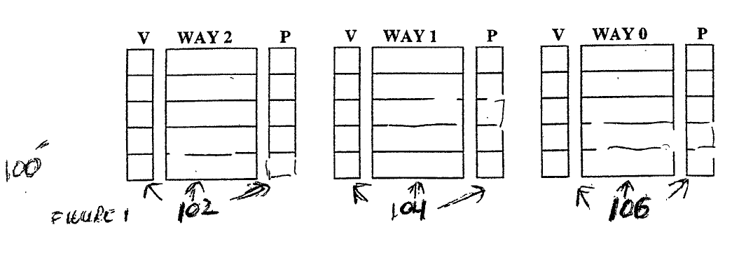

FIG. 1 is a block diagram of a cache memory 100 in accordance with one embodiment. The claimed subject matter supports different cache memory architectures. In one embodiment, the cache memory 100 is a Level 0 cache (L0), the cache that is architecturally and/or physically closest to the computing processor. The claimed subject matter also supports an alternative cache architecture scheme that refers to the closest cache as a Level 1 Cache (L1), rather than a L0 cache. However, the claimed subject matter is not limited to a specific level cache. For example, the cache memory may be a higher order cache, such as, a level two or level three.

In one embodiment, the cache memory represents a tag array for a three way set associative cache, with three ways designated as 102, 104, and 106. Each way 102, 104, and 106 contains a set of cache locations surrounded on each side by a column marked V and another column marked P. Each cache location is designated as a “cache line”. The column marked V indicates whether the specific cache line is valid with respect to a prior art Modified-Exclusive-Shared-Invalid (MESI) protocol. The column marked P indicates whether the specific cache line is functioning properly or has a defect. In one embodiment, a single bit represents the P column and indicates the functionality of the cache line, wherein a binary value of “1” indicates the line is faulty. Alternatively, the P column can be programmed with several bits to indicate the functionality. One advantage of programming with several bits is to ensure a higher level of reliability in the event of a single error rate due to alpha ions. For example, if three bits are utilized to indicate the status of the P column and one bit is flipped from 1 to 0, there would be two of three bits with a binary one value. Thus, the P column would still indicate a faulty line despite an error in one of the P bits.

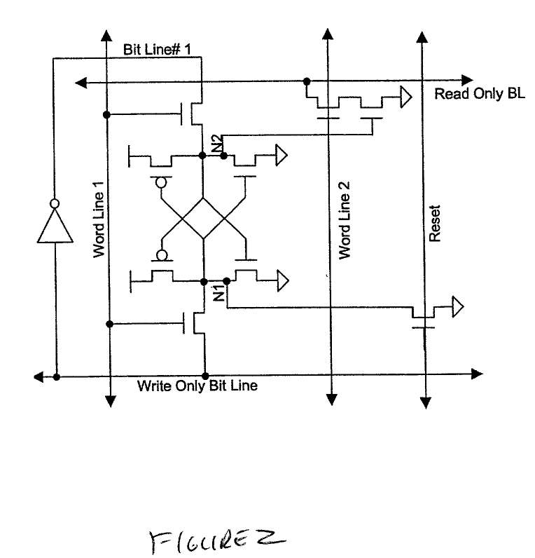

In one embodiment, a conventional six-transistor (6T) static random access memory cell stores the values of the bit or bits represented by the P column. In an alternative embodiment, a conventional register file cell that is well known in the art, represented in FIG. 2, stores the values of the bit or bits represented by the P column. In yet another embodiment, a conventional fuse is programmed to store the value of the bit or bits represented by the P column.

As discussed earlier, the bit or bits in the P column for each way represents the functionality of each cache line. In order to determine the functionality of each cache line, a test of the cache memory 100 is initiated prior to setting the value of the P column bit or bits. In one embodiment, the cache memory is integrated with a processor with a programmable built in self-test (PBIST) logic. The PBIST logic generates a plurality of test patterns to verify the functionality of individual cache lines. Thus, based on the results of the test patterns, the corresponding bit or bits in the P column are set to indicate the functionality of each cache line. In another embodiment, the cache memory is coupled to a processor, and the PBIST logic is incorporated within the cache memory. In yet another embodiment, the cache memory is integrated with a processor that supports low-level software to initiate the diagnostic testing of the cache memory and to set the corresponding bit or bits in the P column. One example of low-level software or firmware is Intel's Platform Architecture Layer. In one embodiment, the bit or bits in the P column are read-only and the PBIST logic has the only ability to update the bit or bits in the P column. The read-only protection of the bit or bits in the P column may be implemented by disabling the PBIST logic during normal operation of the cache memory.

The determination of whether the cache lines are faulty is not limited to PBIST logic or low-level software. For example, automatic test pattern generation (ATPG) patterns may be generated and loaded into a plurality of scan chains within the cache memory. Subsequently, the ATPG patterns are utilized to test the cache memory to determine the functionality of the cache memory, specifically, the cache lines and set the corresponding bit or bits in the P column. In another example, a system incorporating the cache memory may be tested with system level or by functional level tests to verify functionality of the cache lines and set the corresponding bit or bits in the P column.

Although the claimed subject matter has been described with reference to specific embodiments, this description is not meant to be construed in a limiting sense. Various modifications of the disclosed embodiment, as well as alternative embodiments of the claimed subject matter, will become apparent to persons skilled in the art upon reference to the description of the claimed subject matter. It is contemplated, therefore, that such modifications can be made without departing from the spirit or scope of the claimed subject matter as defined in the appended claims.

[image]

1. An apparatus comprising:
a processor, coupled to a cache memory;
the cache memory with a plurality of cache lines, each cache line with at least one status bit to represent whether the cache line contains a defect; and
a logic to perform at least one test of the plurality of cache lines and to set the status bit for at least one of the plurality of cache lines.

2. The apparatus of claim 1 wherein the logic is a programmable built in self-test (PBIST) logic.

3. The apparatus of claim 1 wherein the logic is a plurality of scan chains and a test access port to accept automatic test pattern generation (ATPG) patterns.

4. The apparatus of claim 1 wherein the status bit is stored in a six-transistor static random access memory cell.

5. The apparatus of claim 1 wherein the status bit is stored in a register file cell.

6. The apparatus of claim 1 wherein the status bit is stored in a fuse.

7. The apparatus of claim 1 wherein the status bit is a read only bit during normal operation of the system.

8. The apparatus of claim 1 wherein the cache memory is either one of a level 0 (L0) cache, level 1 (L1) cache, or level 2 (L2) cache.

9. The apparatus of claim 2 wherein the PBIST logic can set the status bit during initialization of the cache memory.

10. An article comprising:
a storage medium having stored thereon instructions, that, when executed by a computing platform, result in execution of testing a processor's cache memory with a plurality of cache lines;
generating a test pattern;
stimulating the cache memory with the test pattern; and
writing to at least one status bit for each cache line to indicate whether the cache line contains a defect.

11. The article of claim 10 wherein the cache memory is either one of a level 0 (L0) cache, level 1 (L1) cache, or level 2 (L2) cache.

12. The article of claim 10 wherein the status bit is stored in either one of a six-transistor static random access memory cell, a register file cell, or a fuse.

13. The article of claim 10 wherein the status bit is a read only bit during normal operation of the cache memory.

14. A method of configuring a cache memory with a plurality of cache lines comprising:
testing the plurality of cache lines;
setting a status bit for at least one cache line to indicate whether the cache line has a defect as a result of the testing; and
disabling the cache lines when the status bit indicates the defect.

15. The method of claim 14 wherein the setting a status bit comprises storing the bit in either one of a six-transistor static random access memory cell, a register file cell, or a fuse.

16. The method of claim 14 wherein the status bit is stored in either one of a six-transistor static random access memory cell, a register file cell, or a fuse.

17. The method of claim 14 wherein the status bit is a read only bit during normal operation of the cache memory.
